(19) United States
(12) Patent Application Publication
(10) Pub. No.: US 2006/0001156 A1
(43) Pub. Date: Jan. 5, 2006

(54) Semiconductor device

(75) Inventors: Satoru Wakiyama, Tokyo (JP); Shinji Baba, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/157,863

(22) Filed: Jun. 22, 2005

(30) Foreign Application Priority Data
Jul. 5, 2004 (JP) 2004-198113

(51) Int. Cl. H01L 23/52

(52) U.S. Cl. 257/737; 257/738; 257/778

(57) ABSTRACT

In a semiconductor device comprising a semiconductor chip, electrodes formed on the major surface of the semiconductor chip, and a wiring board for mounting the semiconductor chip, for example, wirings for electrically connecting the wirings of the wiring board to the electrodes are provided. As the wirings, those relaxing stress generated between the semiconductor chip and the wiring board are used.

### BACKGROUND OF THE INVENTION

1. Field of the Invention

The present invention relates to a semiconductor device. More specifically, the present invention relates to a semiconductor device suited for mounting a flip-chip type of semiconductor chip.

2. Background Art

To cope with the miniaturization of semiconductor devices in recent years, a flip-chip type of semiconductor chip wherein protruded electrodes called a bump are formed on the major surface of a semiconductor chip has been used. When such a semiconductor chip is mounted on a wiring board, bumps formed on the major surface are fitted to the connecting spots of the wiring board using soldering or the like. As a package for packaging these semiconductor chips, for example, a package of a surface-mounted type, such as BGA (ball grid array), has been used (for example, refer to Japanese Patent Application Laid-Open No. 2001-110926).

On the other hand, with the high integration of semiconductor devices in recent years, the use of a low-dielectric-constant film having a low dielectric constant (hereafter referred to as “low-k film”) as an interlayer insulation film has been studied.

The coefficient of linear thermal expansion of the substrate of a semiconductor chip is often different from that of a wiring board for mounting the semiconductor chip, and in many cases, the wiring board has a larger coefficient of linear thermal expansion than the substrate. Therefore, for example, when the semiconductor device is heated in assembling, in reflowing, or in using the semiconductor device, the wiring board is more expanded than the substrate of the semiconductor chip. In addition, since a flip-chip type of semiconductor chip is directly fixed to the wiring board using soldering of bumps or the like, it is influenced by stress due to a large expansion of the wiring board.

A low-k film has a lower strength of the film itself compared with conventional interlayer insulation films, such as SiO₂ films. Therefore, when a low-k film is used as an interlayer insulation film in a semiconductor chip, it is considered that delamination or cracking occurs in the semiconductor chip due to stress as described above.

### SUMMARY OF THE INVENTION

Therefore, the present invention provides a semiconductor device improved so as to suppress the occurrence of delamination, cracking or the like even when mounting a semiconductor chip using a film of a low film strength, such as a low-k film.

According to one aspect of the present invention, a semiconductor device comprises electrode pads formed on the major surface of a semiconductor chip, wirings connected to the electrode pads, and electrodes connected to the wirings. The wirings relax stress generated in the semiconductor chip.

According to another aspect of the present invention, a semiconductor device comprises a semiconductor chip, electrodes formed on the major surface of the semiconductor chip, a wiring board for mounting the semiconductor chip, and redistribution wirings for electrically connecting wirings of the wiring board to the electrodes. The redistribution wirings relax stress generated between the semiconductor chip and the wiring board.

According to another aspect of the present invention, a semiconductor device comprises a semiconductor chip, electrodes formed on the major surface of the semiconductor chip, a wiring board for mounting the semiconductor chip, electrically connected to the electrodes, and a heat-dissipating plate disposed facing the back surface of the semiconductor chip opposite to the major surface, and a stress relaxation resin disposed between the heat-dissipating plate and the back surface of the semiconductor chip.

According to another aspect of the present invention, a semiconductor device comprises a semiconductor chip, electrodes formed on the major surface of the semiconductor chip, a wiring board for mounting the semiconductor chip, and electrically connected to the electrodes, and a heat-dissipating plate disposed facing the back surface of the semiconductor chip opposite to the major surface. The heat-dissipating plate is installed on the wiring board through a heat-dissipating-plate fixer having elasticity.

According to another aspect of the present invention, a semiconductor device comprises a semiconductor chip, electrodes formed on the major surface of the semiconductor chip, and a wiring board for mounting the semiconductor chip, and electrically connected to the electrodes. The wiring board includes a core layer, and two built-up layers disposed across the core layer. Each of the core layer and built-up layers contains glass cloth.

According to another aspect of the present invention, a semiconductor device comprises two semiconductor chips each having electrodes on the major surface, a wiring board disposed between the two semiconductor chips for mounting the semiconductor chips on both surfaces, and redistribution wirings for electrically connecting wirings of the wiring board to the electrodes. The redistribution wirings relax stress generated between the semiconductor chips and the wiring board.

According to another aspect of the present invention, a semiconductor device comprises a wiring board, a semiconductor chip mounted on the wiring board, and encapsulated with an encapsulating member, a mother board for mounting the semiconductor chip with the wiring board, and a heat sink disposed to face the surface of the semiconductor chip opposite to the surface facing the mother board. The heat sink is installed on the mother board through a heat-sink fixer having elasticity.

According to another aspect of the present invention, a semiconductor device comprises two wiring boards, two semiconductor chips mounted on the wiring boards, and encapsulated with encapsulating members, respectively, and a mother board for mounting the semiconductor chips with wiring boards. The two semiconductor chips are mounted on the both side of the mother board across the mother board.

According to another aspect of the present invention, a semiconductor device comprises a semiconductor chip, and a wiring board for mounting the semiconductor chip. At least the side of the semiconductor chip is protected with an encapsulating resin.

Other and further objects, features and advantages of the invention will appear more fully from the following description.

### BRIEF DESCRIPTION OF THE DRAWINGS

FIG. 1 is a schematic sectional view for illustrating a semiconductor device in a first embodiment of the present invention;

FIG. 2 is an enlarged schematic diagram in the vicinity of a rewiring portion for illustrating the rewiring portion of the semiconductor device in a first embodiment of the present invention;

FIG. 3 is a schematic sectional view for illustrating a semiconductor device in the second embodiment of the present invention;

FIGS. 4 and 5 are schematic sectional views for illustrating a semiconductor device in a third embodiment of the present invention;

FIG. 6 is a schematic sectional view for illustrating a semiconductor device in a fourth embodiment of the present invention;

FIG. 7 is a schematic sectional view for illustrating a semiconductor device in a fifth embodiment of the present invention;

FIG. 8 is a schematic sectional view for illustrating a semiconductor device in the sixth embodiment of the present invention;

FIG. 9 is a schematic sectional view for illustrating a semiconductor device in the seventh embodiment of the present invention;

FIG. 10 is a schematic sectional view for illustrating the example of another semiconductor device in the seventh embodiment;

FIG. 11 is a schematic sectional view for illustrating a semiconductor device 800 in the eighth embodiment of the present invention;

FIGS. 12 to 14 are schematic diagrams for illustrating the steps in wafer dicing in the eighth embodiment of the present invention.

### DESCRIPTION OF THE PREFERRED EMBODIMENT

The embodiments of the present invention will be described below referring to the drawings. In the drawings, the same or corresponding parts are denoted by the same reference numerals, and the description thereof will be simplified or omitted. In a flip-chip type of semiconductor chip, the surface on which electrode pads are formed is herein referred to as the “major surface”, and the opposite surface is referred to as the “back surface”, in the specification.

### First Embodiment

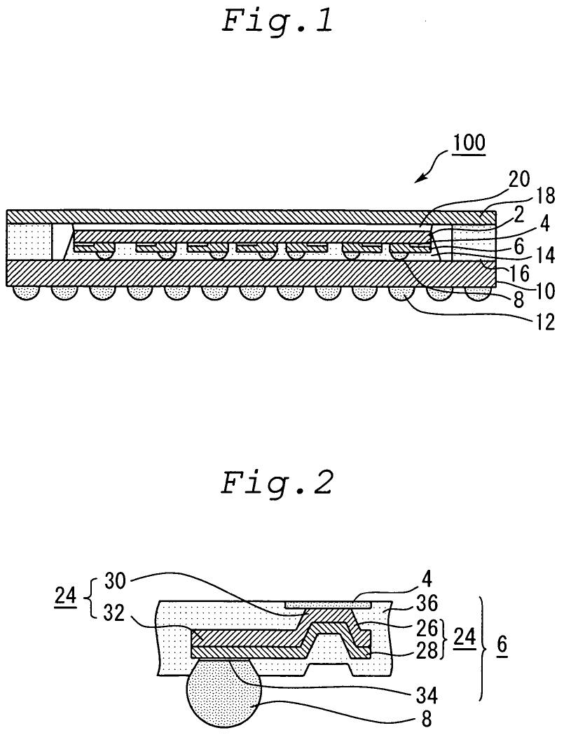

FIG. 1 is a schematic sectional view for illustrating a semiconductor device 100 in a first embodiment of the present invention.

As FIG. 1 shows, the semiconductor device 100 is a semiconductor device wherein a flip-chip type of semiconductor chip 2 is mounted on a BGA (ball grid array) package.

In the semiconductor device 100, the semiconductor chip 2 may be a semiconductor chip using a film having low film strength, such as a low-k film, in the films as the interlayer insulation film.

Electrode pads 4 are formed on the major surface of the semiconductor chip 2. The electrode pads 4 are composed of a metal, such as aluminum (Al). On the electrode pads 4 are formed wiring portions 6 having a structure described below. On the wiring portions 6 are provided inner bumps 8. Specifically, in a conventional semiconductor chip, electrode pads 4 are directly connected to inner bumps 8, whereas in the semiconductor chip 2 mounted on the semiconductor device 100, the wiring portions 6 are disposed between the electrode pads 4 and the inner bumps 8, and the electrode pads 4 are electrically connected to the inner bumps 8 by the wiring portions 6.

The inner bumps 8 are connected to predetermined wirings (not shown) on the wiring board 10. On the wiring board 10 are formed electrodes 12 for drawing out of the package. Specifically, the electrodes 12, the inner bumps 8, the wiring portions 6, and the electrode pads 4 are electrically connected at required locations.

In the state wherein the semiconductor chip 2 is thus mounted on the wiring board 10, the gap between the major surface of the semiconductor chip 2 and the wiring board 10 is filled with a encapsulating resin 14, whereby the element surface of the semiconductor chip 2 is encapsulated on the wiring board 10.

On the circumferential portions of the wiring board 10, spacers 16 are disposed, and leaving a certain distance with the spacers 16, a heat spreader 18 is disposed so as to face the back surface of the semiconductor chip 2. The space between the heat spreader 18 and the back surface of the semiconductor chip 2 is filled with a heat-dissipating resin 20.

FIG. 2 is an enlarged schematic diagram in the vicinity of a wiring portion 6 for illustrating the wiring portion 6 of the semiconductor device 100. The structure and function of the wiring portion 6 will be described below referring to FIG. 2.

As FIG. 2 shows, a wiring 24 is connected to an electrode pad 4. The wiring 24 is composed of a laminate of an Ni layer 26 and a Cu layer 28. The cross section of an end of the wiring 24 has a mountain-shaped protruded portion 30, and the other end has a flat portion 32 connected to the protruded portion 30 in continuity. The protruded portion 30 is connected to the electrode pad 4. The upper portion of the Cu layer 28 on the flat portion 32 is provided with an electrode 34. The electrode 34 is connected to an inner bump 8. In the state wherein the electrode pad 4 on the major surface of the semiconductor chip 2 is connected to the wiring 24, and the electrode 34 is connected to the inner bump 8, the wiring 24 is in the state buried by a stress-buffer film 36. Here, the stress-buffer film 36 is a film consisting, for example, of a polyimide material or BCB (Benzocyclobutene).

In thus formed semiconductor device 100, the coefficient of linear thermal expansion of the wiring board 10 is about 20 ppm/K, and the coefficient of linear thermal expansion of the Si substrate of the semiconductor chip 2 is about 4 ppm/K. Therefore, when the semiconductor device 100 is heated during the assembly or reflow of the semiconductor device 100, the wiring board 10 is larger expanded than the Si substrate because of the difference between the expansion of the wiring board and of the Si substrate.

When the wiring board 10 is more expanded than the semiconductor chip 2, in a conventional structure, the lower surface of the semiconductor chip 2 is directly pulled by the inner bump 8 connected to the wiring board 10. By this stress, in the portion where the strength of the film is low, such as the low-k film in the semiconductor chip 2, delamination or cracking tends to occur.

However, in the semiconductor device 100, the wiring portion 6 is provided between the wiring board 10 and the semiconductor chip 2. By the elastic force of the wiring portion 6, the stress to the semiconductor chip 2 is relaxed. The function of the wiring portion 6 in such cases will be described below.

For example, when the wiring board 10 is larger expanded than the semiconductor chip 2, and pulls the semiconductor chip 2 in the lateral direction in FIG. 2, the protruded portion 30 of the wiring 24 is pulled in the lateral direction, and deformed in the direction so as to open or close the bottom side in the cross section of the protruded portion 30. This deformation relaxes the stress to the semiconductor chip 2.

The stress-buffer film 36 that buries the wiring 24 is a film consisting of polyimide, BCB or the like, and absorbs stress. Specifically, the stress-buffer film 36 is easily deformed to some extent in conjunction with the deformation of the wiring 24, the expansion of the wiring board 10 and the like, and relaxes the stress to the semiconductor chip 2.

In the semiconductor chip 2 of the semiconductor device 100, as described above, the wiring portion 6 having a function to relax stress is disposed between the electrode pad 4 and the inner bump 8. Thereby, while securing the connection between the electrode pad 4 and the inner bump 8, the transmission to the semiconductor chip 2 of the force that the wiring board 10 pulls the semiconductor chip 2 due to expansion can be relaxed. Therefore, the stress to the semiconductor chip 2 can be lowered. Thereby, even when a film having a relatively low strength, such as a low-k film, is used in the semiconductor chip 2, a conventional package and the mounting method thereof can be utilized as they are, while the occurrence of the delamination or cracking of the film in the semiconductor chip 2 can be suppressed. Therefore, a highly reliable semiconductor device can be obtained without significantly changing conventional packages or mounting methods.

In the first embodiment, the use of a laminate of an Ni layer 26 and a Cu layer 28 as the wiring material for the wiring 24 was described. In this case, the strength of Niand Cu, or the ease of Ni and Cu processing is taken into consideration. Specifically, by providing the Ni layer 26, the wiring 24 can be thinned and diffusion from Cu can be prevented. Since Cu has a relatively low strength, by using Cu in a part of the wiring 24, the function as the elastic body to relax stress can be more effectively heightened. In the present invention, however, the material of the wiring 24 is not limited to the laminate of an Ni layer 26 and a Cu layer 28. For example, the wiring 24 can be composed of a single layer of Ni or Cu. The wiring 24 can also be composed of a single layer or laminate of other metals. However, since Ni has a relatively high strength, it must be formed to be thin for some extent. Also since Cu has a relatively low strength, the Cu layer can be thicker than the Ni layer. Since Cu is easy to diffuse, it must be used in combination with a layer to be a barrier metal, such as Ni, in the portions where the diffusion of Cu must be suppressed.

In the first embodiment, the case wherein a stress-buffer film 36 was used so as to bury the wiring 24 was also described. In the present invention, however, when the stress-buffer film is disposed on this location, it can be any film that can be relatively freely deformed corresponding to the expansion of the wiring board 10. For example, a polyimide film, a BCB film, and the like can be considered as such a film.

In the first embodiment, the case using a BGA package was also described. However, the present invention is not limited BGA, but can be applied to the case of mounting in other types of packages. Furthermore, the coefficients of linear thermal expansion of the wiring board 10 and the semiconductor chip 2 described in the first embodiment is merely examples, and do not bind the present invention.

In the first embodiment, for example, the semiconductor chip 2 falls under the “semiconductor chip” of the present invention, and the electrode pad 4 falls under the “electrode pad” or the “electrode formed on the major surface of the chip”. Also for example, the wiring 24 falls under the “wiring” or the “redistribution wiring” of the present invention, and the inner bump 8 falls under the “electrode” of the present invention. Also for example, the wiring board 10 falls under the “wiring board” of the present invention, and the stress-bufferfilm 36 falls under the “stress-buffer film” of the present invention. Furthermore, for example, the protruded portion 30 and the flat portion 32 fall under the “protruded portion” and the “flat portion” of the present invention, respectively.

### Second Embodiment

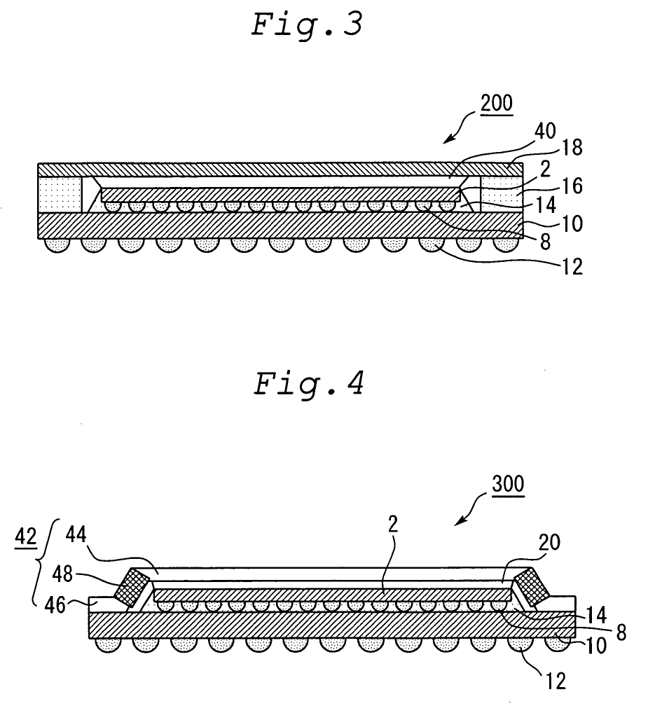

FIG. 3 is a schematic sectional view for illustrating a semiconductor device 200 in the second embodiment of the present invention.

As FIG. 3 shows, in the semiconductor device 200, in the same manner as conventional semiconductor devices, an inner bump 8 is disposed on the major surface of a semiconductor chip 2, and is encapsulated by an encapsulating member 14 in the state wherein the inner bumps 8 are connected to the wiring board 10. A spacer 16 is fixed on the circumferential portion of the wiring board 10, and a heat spreader 18 is fixed so as to face the back surface of the semiconductor chip 2 by the spacer 16.

In the semiconductor device 200, the gap between the heat spreader 18 and the major surface of the semiconductor chip 2 is filled with a gelatinous heat-dissipating resin 40. The examples of gelatinous heat-dissipating resins include a silicone-based resin and the like.

Here, the function of the gelatinous heat-dissipating resin 40 will be described.

The heat spreader 18 is generally in many cases formed of Cu or the like, and Cu has the coefficient of linear thermal expansion is about 20 ppm/K, which is close to the coefficient of linear thermal expansion of the wiring board 10. Whereas, the coefficient of linear thermal expansion of the semiconductor chip 2 is about 4 ppm/K. Therefore, when the semiconductor device 200 is heated during the assembly or reflow of the semiconductor device 200, the heat spreader 18 is larger expanded than the semiconductor chip 2.

For example, in the case of conventional heat dissipating resins, the modulus of elasticity thereof is generally several megapascals or higher. Therefore, when the heat spreader 18 is largely expanded, the force generated by the expansion cannot be well relaxed, and transmitted to the semiconductor chip 2.

On the other hand, in the semiconductor device 200, the gelatinous heat-dissipating resin 40 disposed between the heat spreader 18 and the major surface of the semiconductor chip 2 is a material that flows and deforms relatively freely, and the modulus of elasticity of which is as small as hard to be measured. Therefore, also when the heat spreader 18 is largely expanded, the gelatinous heat-dissipating resin 40 flows and deforms in conjunction with the deformation of the heat spreader 18 due to the expansion thereof. By the deformation of the gelatinous heat-dissipating resin 40, the transmission of the force generated by the expansion of the heat spreader 18 to the semiconductor chip 2 can be suppressed.

As described above, even when the heat spreader 18 is larger expanded than the semiconductor chip 2, the stress to the semiconductor chip 2 can be lowered. Therefore, even when a film having a relatively low strength, such as a low-k film, is used in the semiconductor chip 2, a conventional package and the mounting method thereof can be utilized as they are with the use of the gelatinous heat-dissipating resin 40, while the occurrence of the delamination or cracking of the film in the semiconductor chip 2 can be suppressed. Therefore, a highly reliable semiconductor device can be obtained without significantly changing conventional packages or mounting methods.

Here, the case using a gelatinous heat-dissipating resin 40 was described. However, the present invention is not limited thereto, but for example, a heat-dissipating resin having a modulus of elasticity of 1 Mpa or lower can also be used. Since such a resin can also flow and deform relatively freely in conjunction with the deformation of the heat spreader 18, the stress to the semiconductor chip 2 can be relaxed. Specifically as examples of heat-dissipating resins having a modulus of elasticity of 1 MPa or lower, silicone-based resins can be considered.

In the second embodiment, the case wherein a gelatinous heat-dissipating resin 40 or the like was filled on the back surface of the semiconductor chip 2 of a conventional semiconductor device was described. However, the present invention is not limited thereto, but for example, the heat-dissipating resin 20 in the semiconductor device 100 as described in the first embodiment can be substituted by a gelatinous heat-dissipating resin 40 or a heat-dissipating resin having a modulus of elasticity of 1 MPa or lower as described in the second embodiment. Thereby, the stress to the semiconductor chip 2 due to the expansion of the wiring board 10 and the stress to the semiconductor chip 2 due to the expansion of the heat spreader 18 can be simultaneously relaxed. Since others are same as in the first embodiment, the description thereof will be omitted.

For example, in the second embodiment, the heat spreader 18 falls under the “heat-dissipating plate” of the present invention; and the gelatinous heat-dissipating resin 40 falls under the “gelatinous heat-dissipating resin” of the present invention.

### Third Embodiment

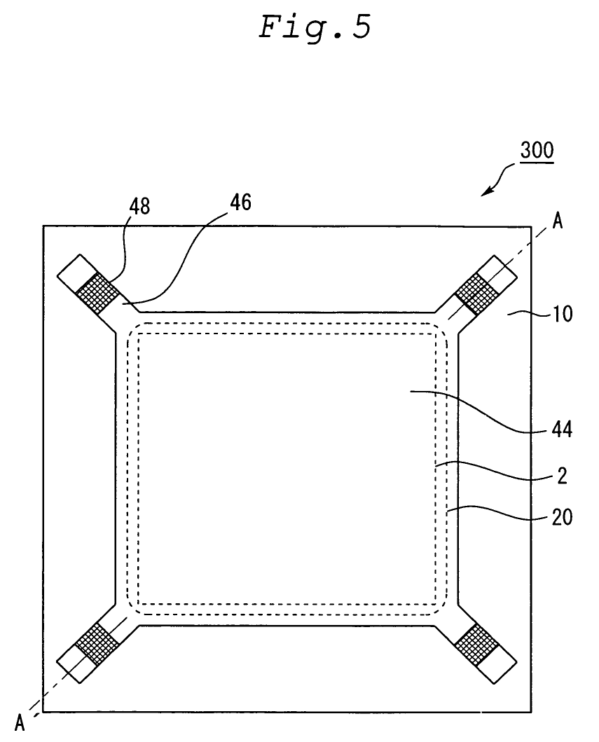

FIGS. 4 and 5 are schematic sectional views for illustrating a semiconductor device 300 in a third embodiment of the present invention, FIG. 4 shows the cross section in the A-A′ direction in FIG. 5, and FIG. 5 shows a top view of the semiconductor device 300.

In the semiconductor device 300, the semiconductor chip 2 is encapsulated by an encapsulating resin 14 in the state wherein the inner bumps 8 provided on the main surface of the semiconductor chip 2 are connected to the wiring board 10.

Although the semiconductor device 300 resembles the semiconductor device 200 in the second embodiment, it is different from the semiconductor device 200 in the shape of the heat spreader 42. Specifically, while the heat spreader 18 of the semiconductor device 200 is connected through the spacer 16, the heat spreader 42 has a shape wherein a spacer is integrated with a heat spreader. Referring to FIG. 5, when viewed from the top, the heat spreader 42 is composed of a square heat-dissipating surface 44 facing the back surface of the semiconductor chip 2, and joint portions 46 radially extending from the four corners of the heat-dissipating surface 44. Referring to FIG. 4, when viewed from the cross-section, the heat-dissipating surface 44 of the heat spreader 42 is protruded so as to dispose the semiconductor chip 2 in the space surrounded by the joint portions 46 and the heat-dissipating surface 44.

Then, in the state wherein the semiconductor chip 2 is disposed in the space, that is under the heat-dissipating surface 44, the tip end portion of the joint portion 46 of the heat spreader 42 are fixed to the four corners of the wiring board 10, respectively. The gap between the upper surface of the semiconductor chip 2 and the heat-dissipating surface 44 of the heat spreader 42 is filled with a heat-dissipating resin 20.

On the portions of the joint portions 46 disposed between the heat-dissipating surface 44 and the wiring board 10, specifically, on the portions located on the sides of the semiconductor chip 2, supporting portions 48 are disposed in the state of leaf springs by folding the heat-dissipating plate.

As described in the second embodiment, the heat spreader 42 has generally a larger coefficient of linear thermal expansion than the semiconductor chip 2. Therefore, the case wherein the heat spreader 42 is largely expanded during assembling or ref lowing is considered. In the semiconductor device 300, however, when the heat spreader 42 is deformed, the supporting portions 48 expand or shrink corresponding to the deformation of the heat spreader 42. By this deformation, the force that the heat spreader 42 pulls the semiconductor chip 2 or the wiring board 10 can be relaxed. Thereby, stress transmitted in the semiconductor chip 2 can be suppressed, and crush or the like at the portion where the strength of the film in the semiconductor chip 2 is small can be suppressed.

In the third embodiment, the case wherein the shape of the heat spreader of a conventional semiconductor device was changed was described. However, the present invention is not limited thereto, but for example, the heat spreader 42 of the third embodiment can be fixed on the wiring board 10 wherein the wiring portions 6 are disposed and the semiconductor chip 2 is mounted as described in the first embodiment. Furthermore, in the third embodiment, the heat-dissipating resin 18 filled between the heat spreader 42 and the semiconductor chip 2 can be substituted by a gelatinous heat-dissipating resin 40 described in the second embodiment, or a heat-dissipating resin having a modulus of elasticity of 1 MPa or lower. In addition, the heat spreader 18 of the first embodiment can be replaced by the heat spreader 42 of the third embodiment, and the gelatinous heat-dissipating resin 40 or the like in the second embodiment can be filled under the heat-dissipating surface 44. By thus combining the first to third embodiments as appropriate, the stress to the semiconductor chip can be more effectively relaxed, and a semiconductor device having high reliability can be obtained.

As the heat spreader 42, a heat spreader having joint portions 46 radially extending from the four corners of the square heat-dissipating surface 44 to the four corners of the wiring board 10 was described above. However, the present invention is not limited thereto, but for example, a part of the joining portions 46 can be replaced by a flat plate composed of an elastic body surrounding the circumference of the wiring board 10.

Furthermore, the case wherein the joining portions 46 was diagonally disposed in the side portions between the wiring board 10 and the heat-dissipating surface 44 was described. However, the present invention is not limited thereto, but for example, the portions disposed on the sides of the joining portions 46 can be formed so as to be disposed vertically above the wiring board 10.

As an example of the supporting portion 48 disposed on the heat spreader joining portion 46, a leaf spring formed by folding a heat-dissipating plate was described. However, the present invention is not limited thereto, but the supporting portion formed from other materials can also be used as long as the materials can expand or shrink to some extent corresponding to the force generated by the thermal expansion of the heat-dissipating surface 44.

For example, the heat-dissipating surface 44 of the heat spreader 42 in the third embodiment falls under the “heat-dissipating plate” of the present invention; and the joining portion 46 including the supporting portion 48 falls under the “heat-dissipating-plate fixer” of the present invention.

### Fourth Embodiment

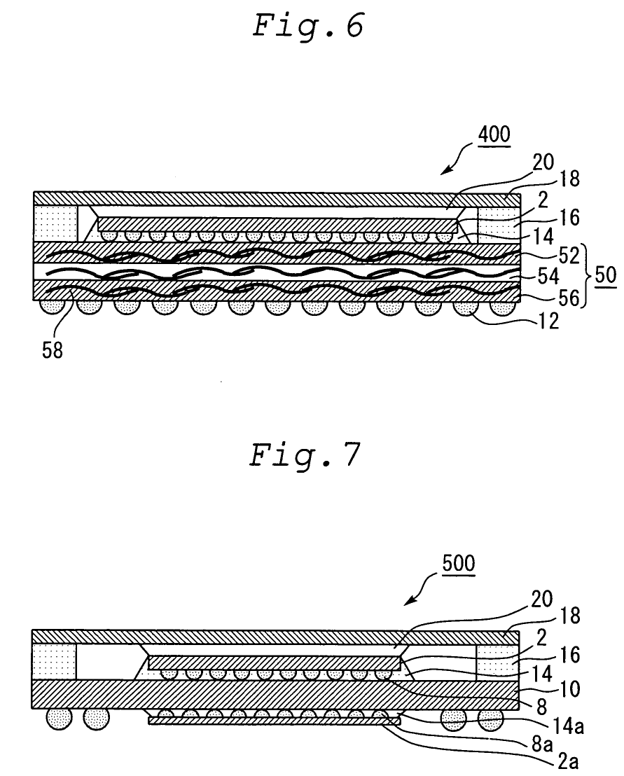

FIG. 6 is a schematic sectional view for illustrating a semiconductor device 400 in a fourth embodiment of the present invention.

As FIG. 6 shows, the semiconductor device 400 resembles a conventional semiconductor device, but has the wiring board 50 of a characteristic structure.

The wiring board 50 in the semiconductor device 400 is composed of a built-up layer 52, a core layer 54, and in addition, a built-up layer 56 under the core layer 54. In the semiconductor device 400 in the fourth embodiment, glass cloth 58 is added in the built-up layers 52 and 56 as well as in the core layer 54, while glass cloth added only in a core layer in the conventional semiconductor device. By containing glass cloth, the rigidities of the built-up layers 52 and 56 and the core layer 54 are reinforced and substantially equalized.

In general, the coefficient of linear thermal expansion of the built-up layer in a conventional wiring board 10 is about 60×10⁻⁶. However, the coefficient of linear thermal expansion of the core layer 54 is about 15×10⁻⁶. In the semiconductor device 400, by also making the built-up layer 52 and 56 contain glass cloth 58, the rigidity of the built-up layer 52 and 56 can be raised, and the coefficient of linear thermal expansion of the built-up layer 52 and 56 can be lowered. As the result, the rigidity of the wiring board 50 can be raised and the coefficient of linear thermal expansion of the wiring board 50 can be lowered. Therefore, since difference in coefficients of linear thermal expansion from the semiconductor chip 2 can be decreased, the stress to the semiconductor chip 2 during assembling or ref lowing can be lowered. Since the rigidity of the wiring board 50 is high, warpage of the entire semiconductor device can be reduced, the force to the semiconductor chip 2 can be lowered. Therefore, even in the film having especially low strength in the semiconductor chip 2, the occurrence of cracking or the like can be prevented, and a semiconductor device having high reliability can be obtained.

In the fourth embodiment, the case wherein only the wiring board 50 was different from conventional semiconductor devices was described. However, the present invention is not limited thereto, but a semiconductor chip 2 having wiring portions 6 described in the first embodiment can be mounted on the wiring board 50 of the fourth embodiment. In place of the heat-dissipating resin 20, the gelatinous heat-dissipating resin 40 of the second embodiment can be used; and in place of the spacer 16 and the heat spreader 18, the heat spreader 42 of the third embodiment can be used. As required, the optional combination of two or more of these can be disposed on the wiring board 50 of the fourth embodiment. Thereby, the stress in the semiconductor chip 2 can be more suppressed, and a semiconductor device, wherein the occurrence of cracking is prevented, having high reliability can be obtained.

Since others are same as in the first to third embodiments, the description thereof will be omitted.

In the fourth embodiment, the core layer 54 falls under the “core layer” of the present invention; and the built-up layers 52 and 56 fall under the “built-up layer” of the present invention.

### Fifth Embodiment

FIG. 7 is a schematic sectional view for illustrating a semiconductor device 500 in a fifth embodiment of the present invention.

In the semiconductor device 500, the semiconductor chip 2 is encapsulated with an encapsulating resin 14 in the state wherein inner bumps 8 provided on the main surface of the semiconductor chip 2 are connected to a surface of the wiring board 10. Furthermore, a heat spreader 18 is disposed facing the back surface of the semiconductor chip 2 through spacers 16.

In the semiconductor device 500, a dummy chip 2a is disposed on the surface of the wiring board 10 opposite to the surface on which the semiconductor chip 2 is mounted. The dummy chip 2a is encapsulated with an encapsulating resin 14a in the state wherein dummy bumps 8a contact the wiring board 10 as in the second embodiment.

Here, the coefficient of linear thermal expansion of the dummy chip 2a is the same as the coefficient of linear thermal expansion of the semiconductor chip 2. By thus disposing the dummy chip 2a, the semiconductor device 500 can be in the state wherein chips having the same coefficient of linear thermal expansion are disposed on the both surfaces of the wiring board 10. Thereby, the tensile stress generated by the expansion of the wiring board 10 to the semiconductor chip 2 can be suppressed. Therefore, even if a film having a low strength is used in the semiconductor chip 2, the occurrence of cracking or the like in a portion of the film or the like can be prevented.

In the fifth embodiment, the case wherein a dummy chip 2a was disposed was described. However, the present invention is not limited thereto, but a semiconductor chip that functions actually can be disposed. In this case, although the semiconductor chips disposed on the both surfaces are not necessarily identical, when the relaxation of the stress generated by the wiring board 10 is considered, the coefficients of linear thermal expansion of the both chips must be the same or close to each other.

In the fifth embodiment, the case wherein a dummy chip 2a was disposed on the surface of the wiring board 10 in the semiconductor device similar to the conventional one, opposite to the surface on which the semiconductor chip 2 was disposed was described. However, the present invention is not limited thereto, but for example, adummy chip or a semiconductor chip that functions actually can be disposed on the back surface of any of the semiconductor devices 100 to 400 described in the first to fourth embodiments. Here, the semiconductor chip disposed on the back surface can be the semiconductor chip described in any of the first to third embodiments. Thereby, the stress to the semiconductor chip 2 can be more effectively reduced, and a semiconductor device having high reliability can be obtained.

Since others are same as in the first to fourth embodiments, the description thereof will be omitted.

For example, the dummy chip 2a in the fifth embodiment falls under the “dummy chip” of the present invention.

### Sixth Embodiment

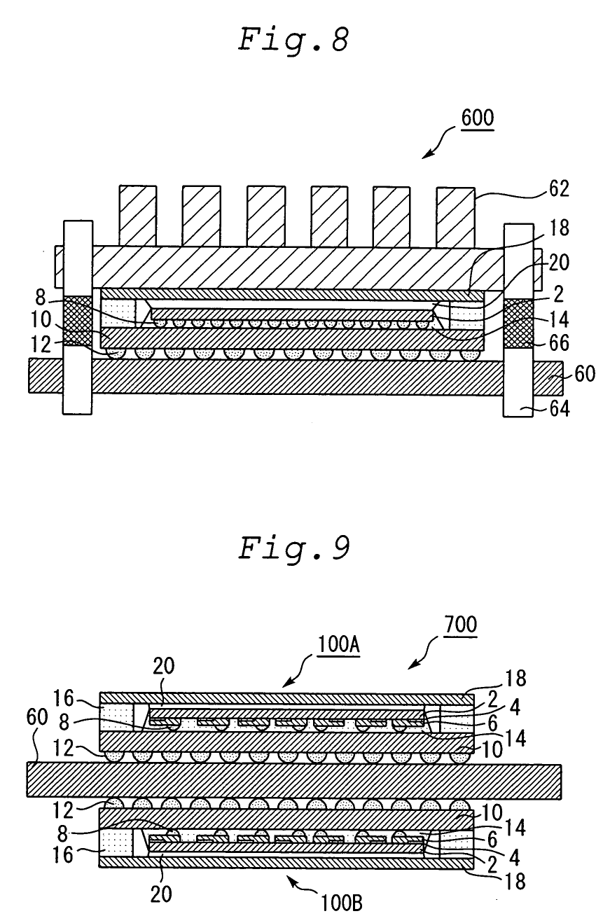

FIG. 8 is a schematic sectional view for illustrating a semiconductor device 600 in the sixth embodiment of the present invention.

As FIG. 8 shows, in the semiconductor device 600, a semiconductor device formed by mounting a semiconductor chip 2 on a wiring board 10 is further mounted on a mother board 60. In the semiconductor device 600, heat sink 62 is disposed on the upper surface of a heat spreader 18. In other words, a conventional semiconductor device is disposed between the mother board 60 and the heat sink 62. The heat sink 62 is fixed on the mother board 60 by heat-sink fixers 64. The heat-sink fixer 64 has an elastic body 66 such as a spring in a portion thereof.

By the constitution of the semiconductor device 600 as described above, the warpage of the heat sink 62 in the heating process of assembling or using the semiconductor device can be coped with the elongation and shrinkage of the elastic body 66, and the force generated by the warpage of the heat sink 62 can be relaxed by the elasticity of the elastic body 66. Therefore, the transmission of the force generated by the warpage of the heat sink 62 to the semiconductor chip 2 can be suppressed. Consequently, even when films having low strength are used in the semiconductor chip 2, cracking or the like can be prevented, and a semiconductor device having high reliability can be obtained.

In the sixth embodiment, the case wherein a conventional semiconductor device was used as the semiconductor device mounted on the mother board 60 was described. However, the present invention is not limited thereto, but for example, any of semiconductor devices 100 to 500 described in the first to fifth embodiments can be mounted on the mother board 60, and the heat sink 62 is fixed using heat-sink fixers 64 having elastic bodies 66. Thereby, stress to the semiconductor chip 2 can be more effectively relaxed.

In the present invention, a spring was shown as an example of the elastic bodies 66. However, the present invention is not limited thereto, but any elastic bodies formed using materials that expand or shrink to some extend corresponding to the force generated by the warpage of the heat sink 62 can be used.

Since other aspects are same as in the first to fifth embodiments, the description thereof will be omitted.

In the sixth embodiment, for example, the mother board 60 and the heat sink 62 fall under the “mother board” and the “heat sink” of the present invention, respectively; and the heat-sink fixer 64 including the elastic body 66 falls under the “heat-sink fixer” of the present invention.

### Seventh Embodiment

FIG. 9 is a schematic sectional view for illustrating a semiconductor device 700 in the seventh embodiment of the present invention.

As FIG. 9 shows, the semiconductor device 700 has a structure wherein semiconductor devices 100A and 100B are mounted on the both sides of a mother board 60, respectively.

Here, both the semiconductor devices 100A and 100B mounted on the mother board 60 have the same structure as the semiconductor device 100 described in the first embodiment.

The coefficient of linear thermal expansion of the mother board 60 is larger than the coefficients of linear thermal expansion of the semiconductor devices 100A and 100B. Therefore, when a semiconductor device is mounted only on one surface, it is considered that the mother board 60 is more shrunk and warped. By this warpage, stress is transmitted to the mounted semiconductor device and furthermore in the semiconductor chip, and the occurrence of delamination or the like in the portion of the semiconductor chip wherein the film strength is low.

However, by the constitution as the semiconductor device 700 of the seventh embodiment, the mother board 60 is held by the semiconductor devices 100A and 100B from the both sides. Therefore, the warpage of the mother board 60 can be prevented, and stress to the semiconductor chip 2 due to the warpage of the mother board 60 can be relaxed. Therefore, even in the portion of the semiconductor chip 2 wherein the film strength is low or the like, cracking, delamination or the like can be prevented.

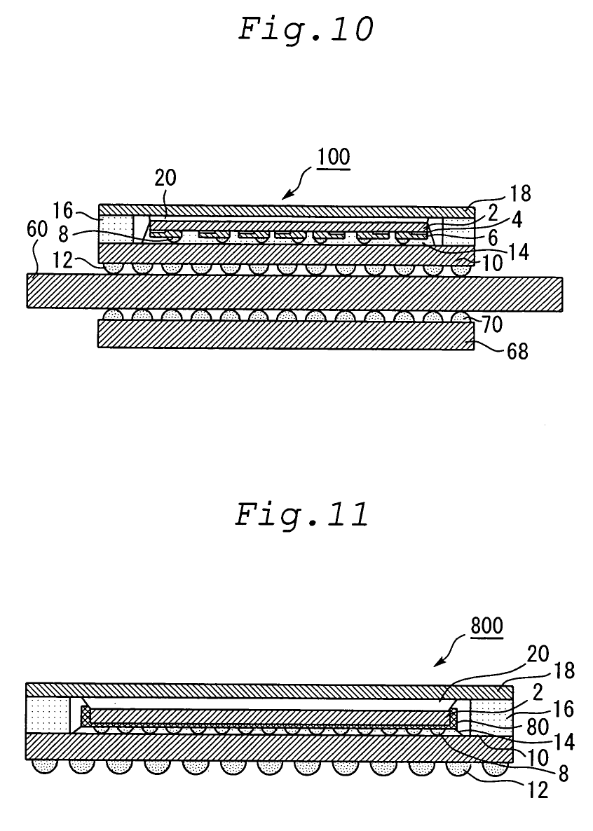

FIG. 10 is a schematic sectional view for illustrating the example of another semiconductor device in the seventh embodiment.

As FIG. 10 shows, the semiconductor device can be of a structure wherein a dummy wiring board 68, instead of the semiconductor device 10B, is fixed on the back surface of the mother board 60 through a dummy electrode 70. Thereby, the stress generated by the warpage of the mother board 60 can be suppressed, cracking or the like in the semiconductor chip 2 can be prevented, and a semiconductor device having high reliability can be obtained.

In the seventh embodiment, the case wherein the semiconductor device 100 described in the first embodiment was mounted on the both sides of the mother board 60 was described. However, the present invention is not limited thereto, but conventional semiconductor devices can be mounted on the both sides of the mother board 60. As FIG. 10 shows, a dummy wiring board 68 can be used on one of them. Furthermore, any of semiconductor devices 200 to 500 described in the second to fifth embodiments can be disposed on the both sides, and a dummy wiring board can be used on one of them. In any case, however, semiconductor devices or wiring boards disposed on the both sides are required to have the same or substantially same coefficient of linear thermal expansion.

As described in the sixth embodiment, the heat sink 62 can be fixed on the mother board 60. The heat sink can be fixed in the same manner as conventional methods.

Since other aspects are same as in the first to sixth embodiments, the description thereof will be omitted.

For example, the semiconductor devices 100A and 100B in the sixth embodiment fall under two semiconductor devices “mounted on the both surfaces of the mother board” of the present invention.

### Eighth Embodiment

FIG. 11 is a schematic sectional view for illustrating a semiconductor device 800 in the eighth embodiment of the present invention.

The semiconductor chip 2 in the semiconductor device 800 in the eighth embodiment has a structure wherein the major surface and the sides are coated with an encapsulating resin 80. By this structure, the low-k film used in the semiconductor chip 2, which have a susceptibility to moisture absorption, can be protected during the dicing of the semiconductor chip 2.

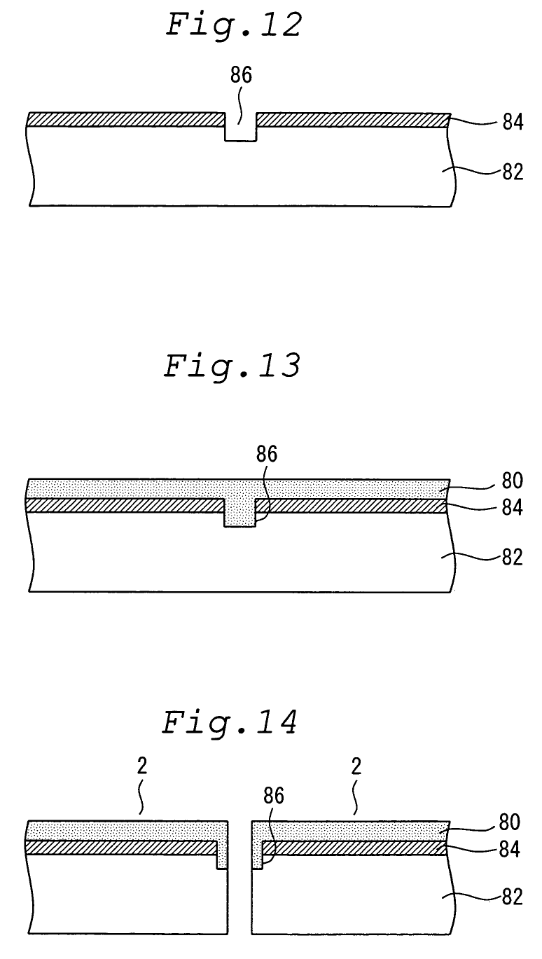

FIGS. 12 to 14 are schematic diagrams for illustrating the steps in wafer dicing in the eighth embodiment.

The steps for dicing a wafer 82 will be described below referring to FIGS. 12 to 14.

First, as FIG. 12 shows, dicing is performed on the side of the major surface 84 of the wafer 82 so as to stop at the depth of about a half the thickness of the wafer 82 or less to form a scribe line 86. Next, as FIG. 13 shows, an encapsulating resin 80 is applied onto the entire major surface 84 of the wafer 82 so as to bury the scribe line 86. The resin has preferably low moisture absorption. Next, as FIG. 14 shows, the dicing of the wafer 82 is performed along the scribe line 86 to the dicing of the wafer 82 is performed to divide it into individual semiconductor chips 2.

By using such a dicing method, stress to the semiconductor chip 2 during dicing can be relaxed, and the occurrence of cracking or the like can be prevented.

In the eighth embodiment, the case wherein a semiconductor device whose sides were protected using the encapsulating resin 86 in place of the conventional semiconductor chip was described. However, the present invention is not limited thereto, but the semiconductor chip diced using this dicing technique can be used as the semiconductor chip 2 to be mounted on any of semiconductor devices 100 to 700 in the first to seventh embodiments. Thereby, the delamination, cracking or the like in the semiconductor chip 2 can be more effectively prevented, and a semiconductor device having high reliability can be obtained.

Since other aspects are same as in the first to seventh embodiments, the description thereof will be omitted.

For example, the encapsulating resin 80 in this embodiment falls under the “resin having a low modulus of elasticity” of the present invention.

The features and advantages of the present invention may be summarized as follows.

According to one aspect of the present invention, stress to a semiconductor chip can be relaxed by difference in coefficients of linear thermal expansion between the semiconductor chip and the wiring board, the mother board, the heat-dissipating plate, or the heat sink. Therefore, stress to the film having a low strength of the film itself, such as a low-k film in the semiconductor chip can be relaxed. Therefore, the occurrence of cracking and delamination in these films can be suppressed, and a semiconductor device having high reliability can be obtained.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2004-198113, filed on Jul. 5, 2004 including specification, claims, drawings and summary, on which the Convention priority of the present application is based, are incorporated herein by reference in its entirety.

1. A semiconductor device comprising:
electrode pads formed on the major surface of a semiconductor chip,
wirings connected to said electrode pads, and
electrodes connected to said wirings, wherein
said wirings relax stress generated in said semiconductor chip.

2. A semiconductor device comprising:
a semiconductor chip,
electrodes formed on the major surface of said semiconductor chip,
a wiring board for mounting said semiconductor chip, and
redistribution wirings for electrically connecting wirings of said wiring board to said electrodes, wherein
said redistribution wirings relax stress generated between said semiconductor chip and said wiring board.

3. The semiconductor device according to claim 2, further comprising a stress-buffer film formed by burying said redistribution wirings, and disposed between said electrodes and said wiring board.

4. The semiconductor device according to claim 2, wherein each of said redistribution wirings has a mountain-shaped protruded portion, and a flat portion connected to said protruded portion in continuity in cross section,
each of said redistribution wiring is connected to said electrodes at said protruded portion, and
is connected to wirings of said wiring board at said flat portion.

5. A semiconductor device comprising:
a semiconductor chip,
electrodes formed on the major surface of said semiconductor chip,
a wiring board for mounting said semiconductor chip, and electrically connected to said electrodes,
a heat-dissipating plate disposed facing the back surface of said semiconductor chip opposite to the major surface, and
a stress relaxation resin disposed between said heat-dissipating plate and the back surface of said semiconductor chip.

6. The semiconductor device according to claim 5, wherein said stress relaxation resin is a gelatinous heat-dissipating resin.

7. The semiconductor device according to claim 5, wherein said stress relaxation resin has an elasticity modulus of 1 MPa or lower.

8. A semiconductor device comprising:
a semiconductor chip,
electrodes formed on the major surface of said semiconductor chip,
a wiring board for mounting said semiconductor chip, and
electrically connected to said electrodes, and
a heat-dissipating plate disposed facing the back surface of said semiconductor chip opposite to the major surface, wherein
said heat-dissipating plate is installed on said wiring board through a heat-dissipating-plate fixer having elasticity.

9. A semiconductor device comprising:
a semiconductor chip,
electrodes formed on the major surface of said semiconductor chip, and
a wiring board for mounting said semiconductor chip, and
electrically connected to said electrodes, wherein said wiring board includes:
a core layer, and
two built-up layers disposed across said core layer; and
each of said core layer and built-up layers contains glass cloth.

10. A semiconductor device comprising:
two semiconductor chips each having electrodes on the major surface,
a wiring board disposed between said two semiconductor chips for mounting said semiconductor chips on both surfaces, and
redistribution wirings for electrically connecting wirings of said wiring board to said electrodes, wherein
said redistribution wirings relax stress generated between said semiconductor chips and said wiring board.

11. The semiconductor device according to claim 10, wherein
one of said two semiconductor chips is a dummy chip, and
the other of said two semiconductor chips and said dummy chip have a substantially identical coefficient of linear thermal expansion.

12. A semiconductor device comprising:
a wiring board,
a semiconductor chip mounted on said wiring board, and encapsulated with an encapsulating member,
a mother board for mounting said semiconductor chip with said wiring board, and
a heat sink disposed to face the surface of said semiconductor chip opposite to the surface facing said mother board, wherein
said heat sink is installed on said mother board through a heat-sink fixer having elasticity.

13. A semiconductor device comprising:
two wiring boards,
two semiconductor chips mounted on said wiring boards, and encapsulated with encapsulating members, respectively, and
a mother board for mounting said semiconductor chips with wiring boards, wherein
said two semiconductor chips are mounted on the both side of said mother board across said mother board.

14. A semiconductor device comprising:
a semiconductor chip, and
a wiring board for mounting said semiconductor chip, wherein
at least the side of said semiconductor chip is protected with an encapsulating resin.
